(19) United States
(12) Patent Application Publication
(10) Pub. No.: US 2013/0126959 A1
(43) Pub. Date: May 23, 2013

(54) SEMICONDUCTOR DEVICE AND METHOD OF MANUFACTURING SEMICONDUCTOR DEVICE

(71) Applicants: Ryota Aburada, Kanagawa (JP); Takashi Obara, Kanagawa (JP); Toshiya Kotani, Tokyo (JP)

(72) Inventors: Ryota Aburada, Kanagawa (JP); Takashi Obara, Kanagawa (JP); Toshiya Kotani, Tokyo (JP)

(21) Appl. No.: 13/613,473

(22) Filed: Sep. 13, 2012

(30) Foreign Application Priority Data
Nov. 22, 2011 (JP) 2011-254854

(51) Int. Cl. H01L 27/088; H01L 21/302; H01L 21/336; H01L 29/02

(52) U.S. Cl. 257/324; 257/618; 438/696; 438/269; 257/E29.002; 257/E27.06; 257/E21.214; 257/E21.41

(57) ABSTRACT

According to one embodiment, there are provided a first shaped pattern in which a plurality of first holes are arranged and of which a width is periodically changed along an arrangement direction of the first holes, a second shaped pattern in which a plurality of second holes are arranged and of which a width is periodically changed along an arrangement direction of the second holes, and slits which are formed along the arrangement direction of the first holes and separate the first shaped pattern and the second shaped pattern.

### CROSS-REFERENCE TO RELATED APPLICATIONS

This application is based upon and claims the benefit of priority from Japanese Patent Application No. 2011-254854, filed on Nov. 22, 2011; the entire contents of which are incorporated herein by reference.

### FIELD

Embodiments disclosed herein relate generally to a semiconductor device and a method of manufacturing the semiconductor device.

### BACKGROUND

Memory cells are three-dimensionally disposed in order to increase the capacity per chip in a nonvolatile semiconductor storage device such as a NAND flash memory. In order to form such memory cells, it is necessary to provide holes for forming the memory cells in a cylindrical shape and to put slits between the memory cells for separation.

### BRIEF DESCRIPTION OF THE DRAWINGS

FIG. 1A is a plan view illustrating a method of manufacturing a semiconductor device according to a first embodiment, FIG. 1B is a cross-sectional view illustrating the semiconductor device taken along the line A-A′ of FIG. 1A, and FIG. 1C is a cross-sectional view illustrating the semiconductor device taken along the line B-B′ of FIG. 1A;

FIG. 2A is a plan view illustrating the method of manufacturing the semiconductor device according to the first embodiment, FIG. 2B is a cross-sectional view illustrating the semiconductor device taken along the line A-A′ of FIG. 2A, and FIG. 2C is a cross-sectional view illustrating the semiconductor device taken along the line B-B′ of FIG. 2A;

FIG. 3A is a plan view illustrating the method of manufacturing the semiconductor device according to the first embodiment, FIG. 3B is a cross-sectional view illustrating the semiconductor device taken along the line A-A′ of FIG. 3A, and FIG. 3C is a cross-sectional view illustrating the semiconductor device taken along the line B-B′ of FIG. 3A;

FIG. 4A is a plan view illustrating the method of manufacturing the semiconductor device according to the first embodiment, FIG. 4B is a cross-sectional view illustrating the semiconductor device taken along the line A-A′ of FIG. 4A, and FIG. 4C is a cross-sectional view illustrating the semiconductor device taken along the line B-B′ of FIG. 4A;

FIG. 5A is a plan view illustrating the method of manufacturing the semiconductor device according to the first embodiment, FIG. 5B is a cross-sectional view illustrating the semiconductor device taken along the line A-A′ of FIG. 5A, and FIG. 5C is a cross-sectional view illustrating the semiconductor device taken along the line B-B′ of FIG. 5A;

FIG. 6A is a plan view illustrating the method of manufacturing the semiconductor device according to the first embodiment, FIG. 6B is a cross-sectional view illustrating the semiconductor device taken along the line A-A′ of FIG. 6A, and FIG. 6C is a cross-sectional view illustrating the semiconductor device taken along the line B-B′ of FIG. 6A;

FIG. 7A is a plan view illustrating a method of manufacturing a semiconductor device according to a second embodiment, FIG. 7B is a cross-sectional view illustrating the semiconductor device taken along the line A-A′ of FIG. 7A, and FIG. 7C is a cross-sectional view illustrating the semiconductor device taken along the line B-B′ of FIG. 7A;

FIG. 8A is a plan view illustrating the method of manufacturing the semiconductor device according to the second embodiment, FIG. 8B is a cross-sectional view illustrating the semiconductor device taken along the line A-A′ of FIG. 8A, and FIG. 8C is a cross-sectional view illustrating the semiconductor device taken along the line B-B′ of FIG. 8A;

FIG. 9A is a plan view illustrating the method of manufacturing the semiconductor device according to the second embodiment, FIG. 9B is a cross-sectional view illustrating the semiconductor device taken along the line A-A′ of FIG. 9A, and FIG. 9C is a cross-sectional view illustrating the semiconductor device taken along the line B-B′ of FIG. 9A;

FIG. 10A is a plan view illustrating the method of manufacturing the semiconductor device according to the second embodiment, FIG. 10B is a cross-sectional view illustrating the semiconductor device taken along the line A-A′ of FIG. 10A, and FIG. 10C is a cross-sectional view illustrating the semiconductor device taken along the line B-B′ of FIG. 10A;

FIG. 11A is a plan view illustrating the method of manufacturing the semiconductor device according to the second embodiment, FIG. 11B is a cross-sectional view illustrating the semiconductor device taken along the line A-A′ of FIG. 11A, and FIG. 11C is a cross-sectional view illustrating the semiconductor device taken along the line B-B′ of FIG. 11A;

FIG. 12A is a plan view illustrating a method of manufacturing a semiconductor device according to a third embodiment, FIG. 12B is a cross-sectional view illustrating the semiconductor device taken along the line A-A′ of FIG. 12A, and FIG. 12C is a cross-sectional view illustrating the semiconductor device taken along the line B-B′ of FIG. 12A;

FIG. 13A is a plan view illustrating the method of manufacturing the semiconductor device according to the third embodiment, FIG. 13B is a cross-sectional view illustrating the semiconductor device taken along the line A-A′ of FIG. 13A, and FIG. 13C is a cross-sectional view illustrating the semiconductor device taken along the line B-B′ of FIG. 13A;

FIGS. 14A to 14C are plan views illustrating a method of disposing a grid for collectively forming holes and slits according to a fourth embodiment;

FIG. 15 is a plan view illustrating an example of disposing the holes and the slits in the grid of FIG. 14A;

FIGS. 16A to 16H are plan views illustrating an example of disposing holes and slits according to a fifth embodiment;

FIG. 17A is a perspective view illustrating an example of stacking holes and slits according to a sixth embodiment, and FIG. 17B is a perspective view illustrating an example of stacking holes and slits according to a seventh embodiment;

FIG. 18 is a circuit diagram illustrating a schematic configuration of a memory cell array which is applied to a nonvolatile semiconductor storage device according to an eighth embodiment;

FIG. 19 is a perspective view illustrating a schematic configuration example of the memory cell array of the nonvolatile semiconductor storage device of FIG. 18;

FIG. 20 is a cross-sectional view illustrating a portion E of FIG. 19 in an enlarged manner; and

FIGS. 21A to 21D are cross-sectional views illustrating a method of manufacturing a memory cell array which is applied to a nonvolatile semiconductor storage device according to a ninth embodiment.

### DETAILED DESCRIPTION

In general, according to one embodiment, a semiconductor device is provided with a first shaped pattern, a second shaped pattern, and a slit. In the first shaped pattern, a plurality of first holes are arranged, and widths therebetween are periodically changed along an arrangement direction of the first holes. In the second shaped pattern, a plurality of second holes are arranged, and widths therebetween are periodically changed along an arrangement direction of the second holes. The slit is formed along the arrangement direction of the holes, and separates the first shaped pattern from the second shaped pattern.

Hereinafter, a semiconductor device and a method of manufacturing the semiconductor device according to embodiments will be described with reference to the drawings. Further, the invention is not limited to these embodiments.

### First Embodiment

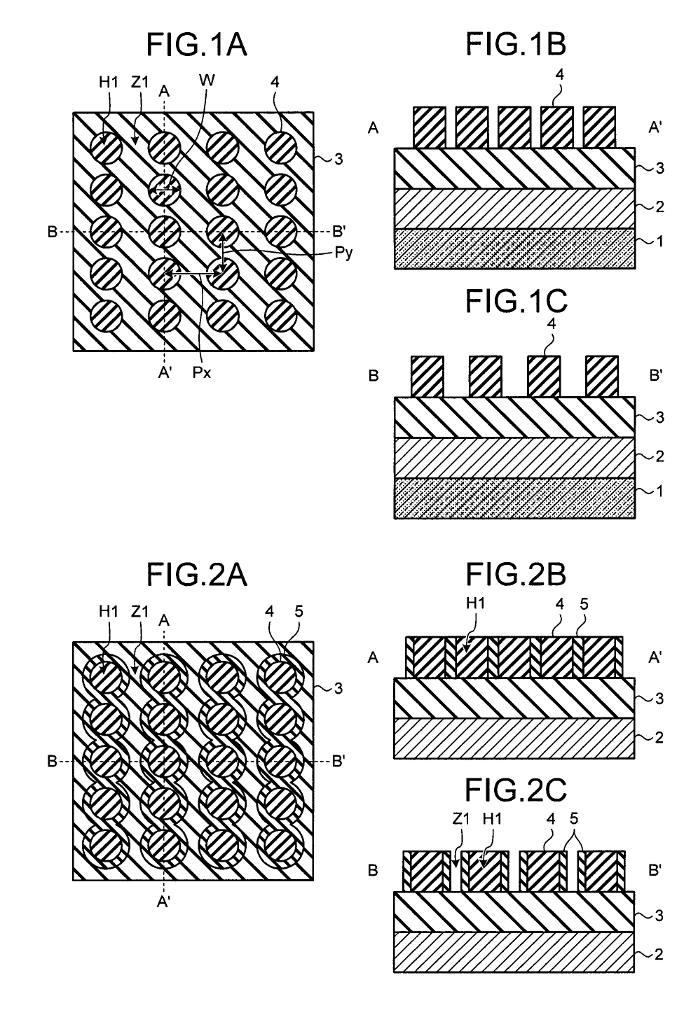

FIGS. 1A to 6A are plan views illustrating a method of manufacturing a semiconductor device according to a first embodiment, FIGS. 1B to 6B respectively are cross-sectional views illustrating the semiconductor device taken along the line A-A′ of FIGS. 1A to 6A, and FIGS. 1C to 6C respectively are cross-sectional views illustrating the semiconductor device taken along the line B-B′ of FIGS. 1A to 6A.

In FIGS. 1A to 1C, a processing target film 2 is formed on a foundation layer 1, and a mask layer 3 is formed on the processing target film 2. Further, the foundation layer 1 may be a semiconductor board or may be an insulating layer or the like formed on the semiconductor board, which is not particularly limited. In addition, as a material of the processing target film 2, a polycrystalline silicon film used for a word line and the like may be exemplified. Alternatively, a material of the processing target film 2 may be metal such as Al or Cu. Alternatively, the processing target film 2 may be a stacked body including the polycrystalline silicon film and an insulating body. In addition, the mask layer 3 may be an organic film such as a resist film or may be an inorganic film such as a silicon dioxide film.

With the use of a photolithography technique and an etching technique, core material patterns 4 are formed on the mask layer 3. At this time, the core material patterns 4 may be arranged such that the pitch Py thereof in the vertical direction is narrower than the pitch Px in the horizontal direction. Further, a material of the core material pattern 4 may employ a resist material, or may employ a hard mask material such as a BSG film and a silicon nitride film. In addition, the shape of the core material pattern 4 may be a cylindrical shape having a diameter W, or may be a prismatic shape. In addition, using a method such as an isotropic etching, the core material patterns 4 may be formed to be slim so as to reduce the diameters of the core material patterns 4.

Next, as illustrated in FIGS. 2A to 2C, a side wall material which has a high selectivity to the core material patterns 4 is deposited on the entire surface of the mask layer 3 including side walls of the core material patterns 4, for example, using a method such as a CVD. Further, as a side wall material having a high selectivity to the core material patterns 4, for example, the silicon nitride film may be used in a case where the core material patterns 4 are made of the BSG film. Then, through an anisotropic etching performed on the side wall material, the mask layer 3 is exposed while the side wall material is left on the side walls of the core material patterns 4. At this time, side wall patterns 5 are formed on outer peripheries of the core material patterns 4. The side wall patterns 5 may be formed successively in the vertical direction and separately in the horizontal direction. At this time, in the side wall patterns 5, slits Z1 are formed to separate the side wall patterns 5 in the horizontal direction, and holes H1 are formed to be arranged in the vertical direction with the side wall patterns 5 interposed therebetween. On this stage, the holes H1 are filled with the core material patterns 4.

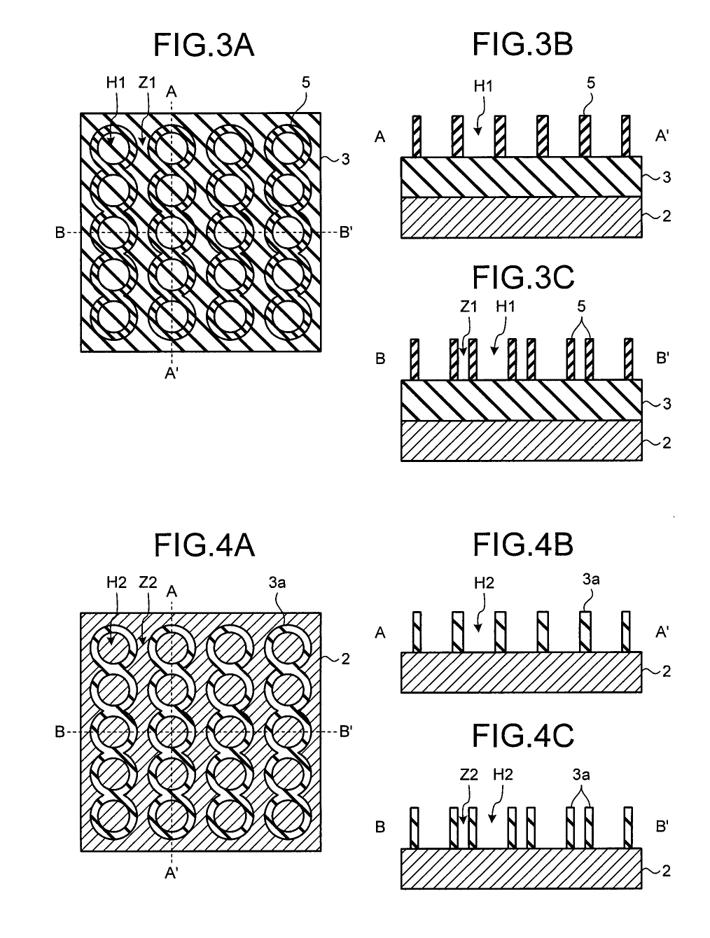

Next, as illustrated in FIGS. 3A to 3C, while the side wall patterns 5 are left on the mask layer 3, the core material patterns 4 are removed from the mask layer 3 using the photolithography technique and the etching technique.

Next, as illustrated in FIGS. 4A to 4C, the mask layer 3 is etched through the side wall patterns 5. Accordingly, mask patterns 3a on which the side wall patterns 5 are transferred are formed on the foundation layer 1. Herein, the mask patterns 3a may be formed successively in the vertical direction and separately in the horizontal direction. At this time, in the mask patterns 3a, slits Z2 are formed to separate the mask patterns 3a in the horizontal direction, and holes H2 are formed to be arranged in the vertical direction with the mask pattern 3a interposed therebetween.

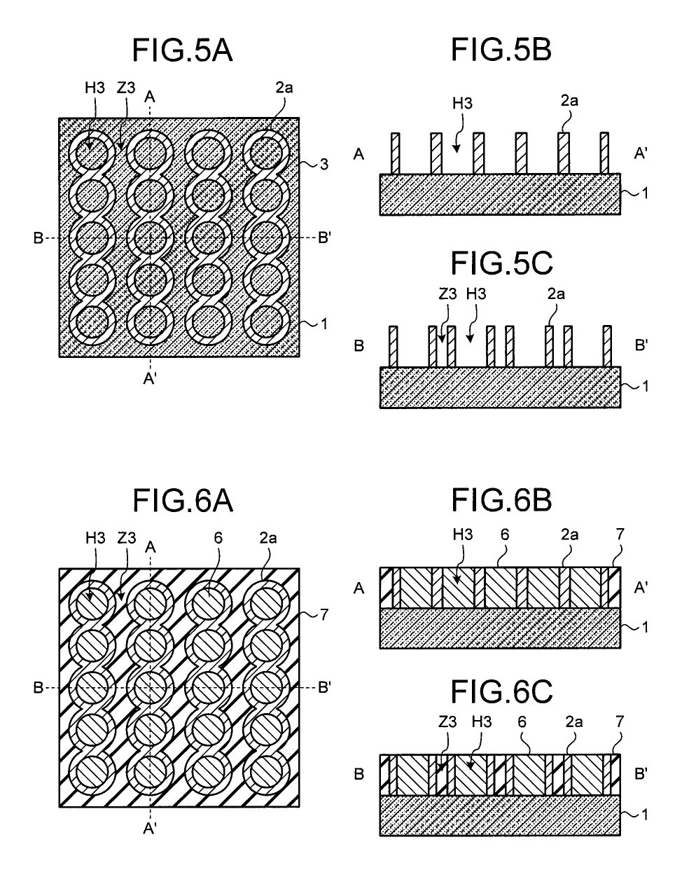

Next, as illustrated in FIGS. 5A to 5C, the processing target film 2 is etched through the mask patterns 3a. Accordingly, shaped patterns 2a on which the mask patterns 3a are transferred are formed on the foundation layer 1. Herein, the shaped patterns 2a may be formed successively in the vertical direction and separately in the horizontal direction. At this time, in the shaped patterns 2a, slits Z3 are formed to separate the shaped patterns 2a in the horizontal direction, and holes H3 are formed to be arranged in the vertical direction with the shaped patterns 2a interposed therebetween.

Next, as illustrated in FIGS. 6A to 6C, the slits Z3 are filled with a buried material. Accordingly, line patterns 7 are formed in the slits Z3. In addition, the holes H3 are filled with the buried material. Accordingly, via patterns 6 are formed in the holes H3. Further, the via patterns 6 and the line patterns 7 each may be formed of different materials, or may be formed of the same material. In addition, the materials of the via patterns 6 and the line patterns 7 may be a conductor such as Al or Cu, a semiconductor such as Si or SiGe, or an insulating body such as a silicon dioxide film.

Herein, using the side wall patterns 5 formed with the slits Z1 and the holes H1 as an etching mask, the holes H3 can be miniaturized and the holes H3 and the slits Z3 can be collectively formed in the processing target film 2. For this reason, alignment accuracy can be enhanced compared with the case where the holes H3 and the slits Z3 are formed in separated processes, and the number of processes can be reduced.

Further, in the above-described embodiment, the method of etching the processing target film 2 through the mask patterns 3a in order to collectively form the holes H3 and the slits Z3 in the processing target film 2 has been described. On the contrary, the processing target film 2 may be etched through the side wall patterns 5 without forming the mask layer 3 on the processing target film 2 in order to collectively form the holes H3 and the slits Z3 in the processing target film 2.

### Second Embodiment

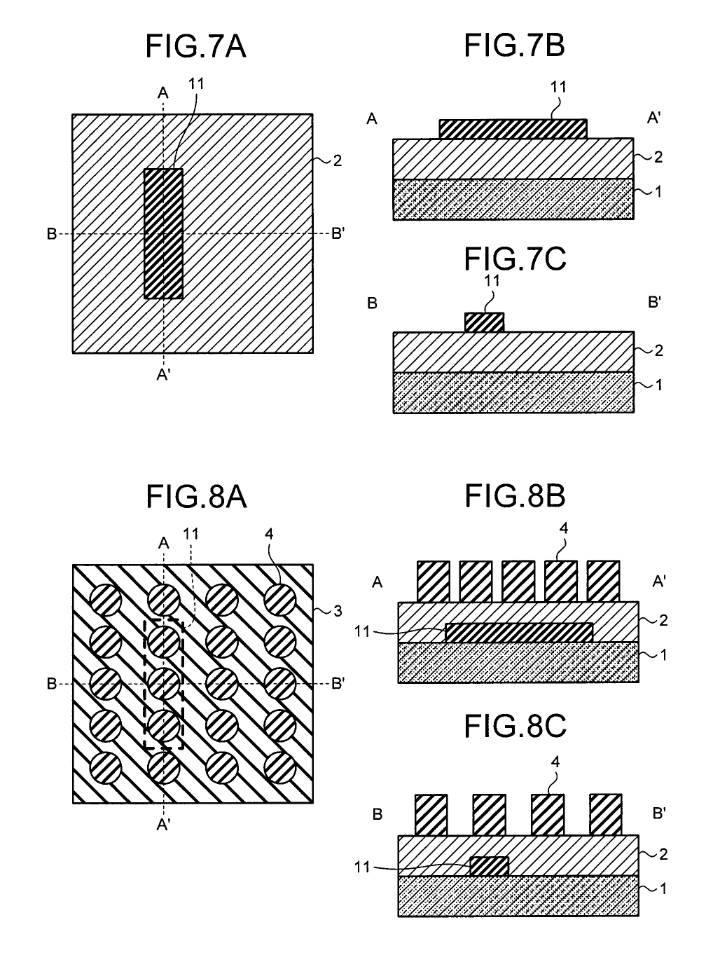

FIGS. 7A to 11A are plan views illustrating a method of manufacturing a semiconductor device according to a second embodiment, FIGS. 7B to 11B respectively are cross-sectional views illustrating the semiconductor device taken along the line A-A′ of FIGS. 7A to 11A, and FIGS. 7C to 11C respectively are cross-sectional views illustrating the semiconductor device taken along the line B-B′ of FIGS. 7A to 11A.

In FIGS. 7A to 7C, the processing target film 2 is formed on the foundation layer 1. Then, a stopper material is formed as a film on the processing target film 2 using a method such as the CVD. Then, a stopper pattern 11 is formed on the processing target film 2 by patterning the stopper material using the photolithography technique and the etching technique. Thereafter, the mask layer 3 is formed on the processing target film 2 using a method such as the CVD. Further, the stopper pattern 11 may be formed using a material having a high selectivity to the mask layer 3 and the processing target film 2. For example, in a case where the mask layer 3 is formed of a silicon dioxide film and the processing target film 2 is formed of a polycrystalline silicon film, the silicon nitride film may be used as a material of the stopper pattern 11.

Next, as illustrated in FIGS. 8A to 8C, the core material patterns 4 are formed on the mask layer 3 using the photolithography technique and the etching technique.

Next, similarly to the processes illustrated in FIGS. 2A to 2C, the side wall material having a high selectivity to the core material patterns 4 is deposited on the entire surface of the mask layer 3 including the side walls of the core material patterns 4. Next, similarly to the processes illustrated in FIGS. 3A to 3C, while the side wall patterns 5 are left on the mask layer 3, the core material patterns 4 are removed from the mask layer 3 using the photolithography technique and the etching technique.

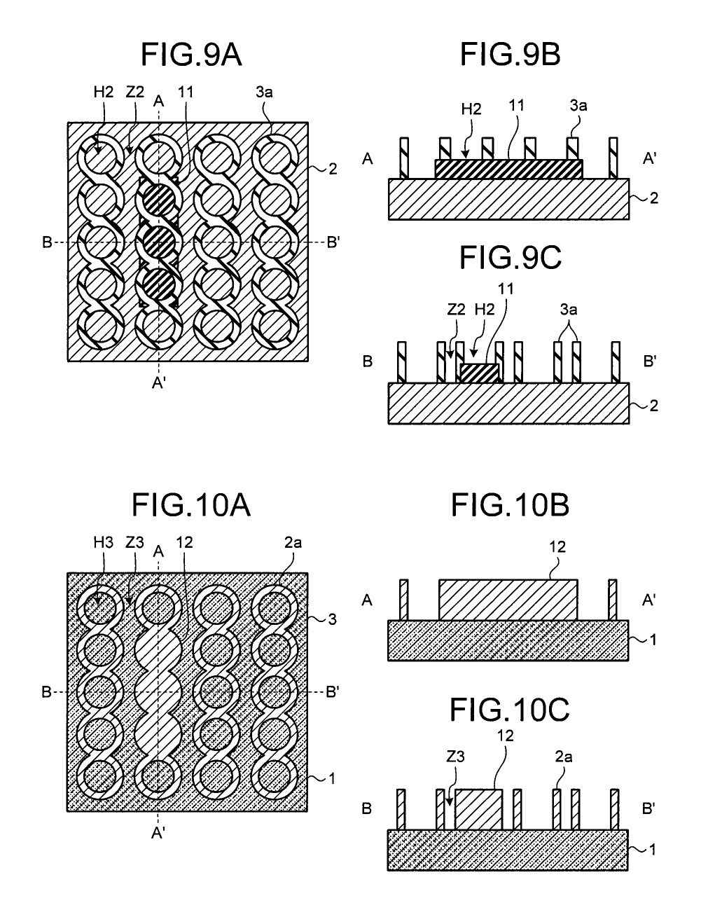

Next, as illustrated in FIGS. 9A to 9C, the mask layer 3 is etched through the side wall patterns 5. Accordingly, the mask patterns 3a on which the side wall patterns 5 are transferred are formed on the foundation layer 1. Herein, since the stopper pattern 11 has a high selectivity to the mask layer 3, it is possible to prevent the stopper pattern 11 from being etched at the time of etching the mask layer 3.

Next, as illustrated in FIGS. 10A to 10C, the processing target film 2 is etched through the mask patterns 3a and the stopper pattern 11. Accordingly, the shaped patterns 2a on which the mask patterns 3a are transferred are formed on a foundation layer 2 and a solid pattern 12 on which the stopper pattern 11 is transferred is formed on the foundation layer 2. Herein, since the stopper pattern 11 has a high selectivity to the processing target film 2, it is possible to prevent the stopper pattern 11 from being etched at the time of etching the processing target film 2.

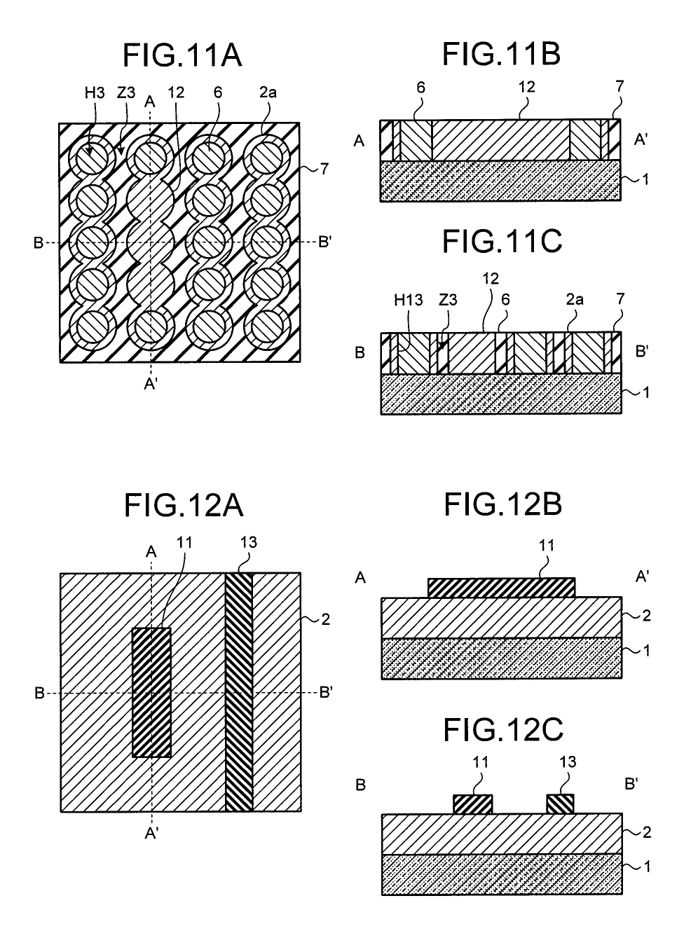

Next, as illustrated in FIGS. 11A to 11C, the slits Z3 are filled with the buried material. Accordingly, the line patterns 7 are formed in the slits Z3. In addition, the holes H3 are filled with the buried material, so that the via patterns 6 are formed in the holes H3.

Herein, the stopper pattern 11 is provided on the processing target film 2. Therefore, the holes H3 and the slits Z3 can be collectively formed in the processing target film 2, and it is possible to prevent the holes H3 or the slits Z3 from being formed in a specific area of the processing target film 2.

### Third Embodiment

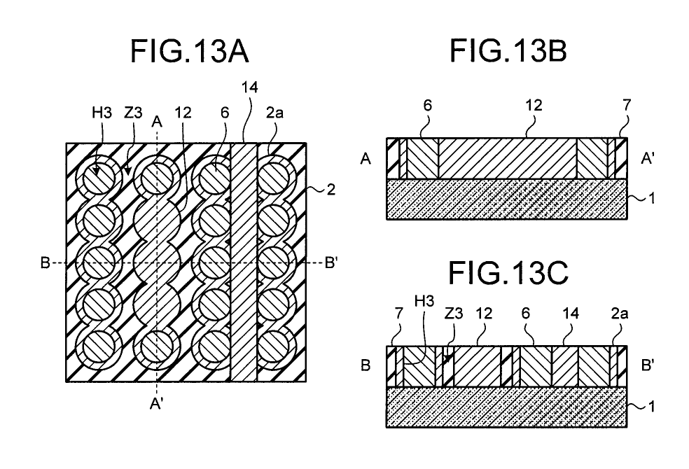

FIGS. 12A and 13A are plan views illustrating a method of manufacturing a semiconductor device according to a third embodiment, FIGS. 12B and 13B respectively are cross-sectional views illustrating the semiconductor device taken along the line A-A′ of FIGS. 12A and 13A, and FIGS. 12C and 13C are cross-sectional views illustrating the semiconductor device taken along the line B-B′ of FIGS. 12A and 13A.

In FIGS. 12A to 12C, in the third embodiment, a stopper pattern 13 is formed on the processing target film 2 in addition to the stopper pattern 11 illustrated in FIGS. 7A to 7C.

Next, as illustrated in FIGS. 13A to 13C, through the same processes illustrated in FIGS. 8A to 8C, FIGS. 9A to 9C, FIGS. 10A to 10C, and FIGS. 11A to 11C, the shaped patterns 2a on which the mask patterns 3a are transferred are formed on the foundation layer 1, and solid patterns 12 and 14 on which the stopper patterns 11 and 13 respectively are transferred are formed on the foundation layer 2.

### Fourth Embodiment

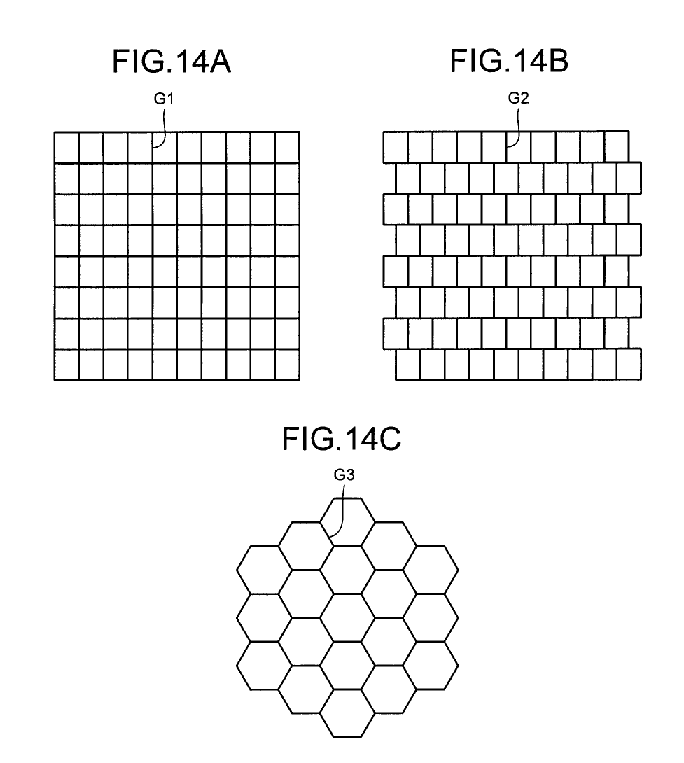

FIGS. 14A to 14C are plan views illustrating a method of disposing a grid for collectively forming holes and slits according to a fourth embodiment.

In FIGS. 14A to 14C, in a case where the core material patterns 4 are disposed, grids G1 to G3 are set. Further, the sizes of the grids G1 to G3 can be set to correspond to the minimum size of the holes H3 formed on the processing target film 2. Herein, as illustrated in FIG. 14A, the grid G1 may be set in a lattice pattern. Alternatively, as illustrated in FIG. 14B, the grid G2 may be set such that lattices are shifted by a half pitch for each row. Alternatively, as illustrated in FIG. 14C, a hexagonal grid G3 may be employed.

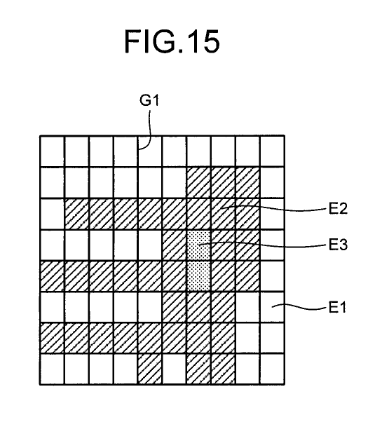

FIG. 15 is a plan view illustrating an example of disposing the holes and the slits in the grid of FIG. 14A.

In FIG. 15, for example, the slits Z3 are disposed on areas El on the grid G1 of FIG. 14A, the holes H3 are disposed on areas E2, and no holes H3 and no slits Z3 are formed on areas E3. In this case, the core material patterns 4 may be disposed on areas E2, and the stopper pattern 11 may be disposed on areas E3.

### Fifth Embodiment

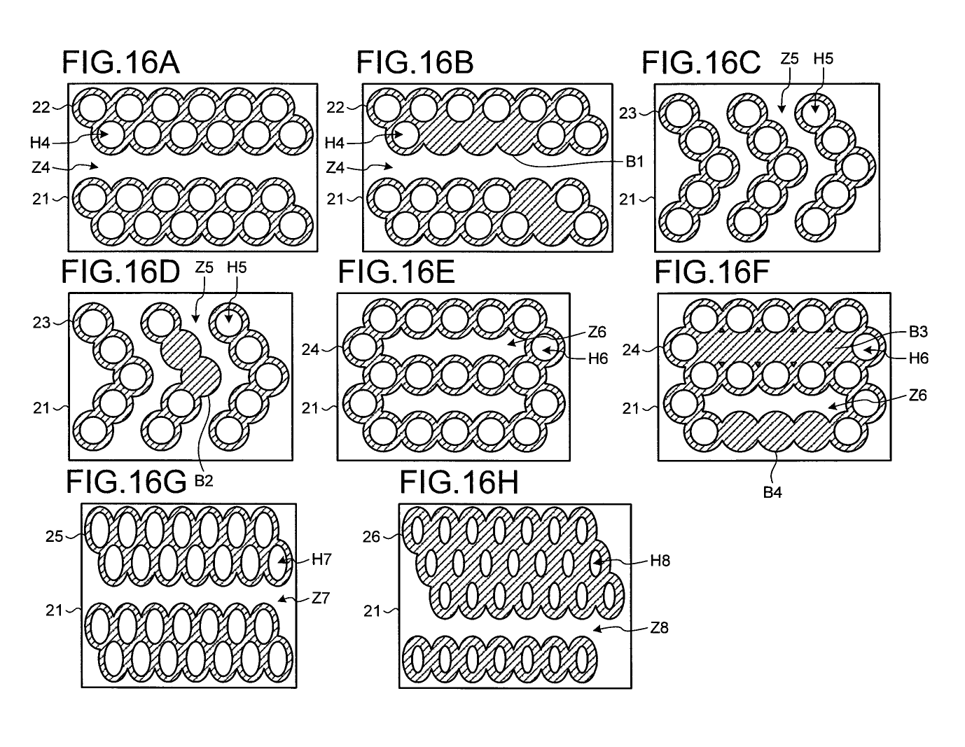

FIGS. 16A to 16H are plan views illustrating an example of disposing holes and slits according to a fifth embodiment.

In FIG. 16A, shaped patterns 22 are formed in a foundation layer 21. Herein, in the shaped patterns 22, slits Z4 are formed in the horizontal direction, and holes H4 are arranged in the horizontal direction. At this time, the shape of the hole H4 may be a circle. In addition, as illustrated in FIG. 16B, some of the holes H4 may be formed in a solid pattern B1.

In FIG. 16C, shaped patterns 23 are formed in the foundation layer 21. Herein, in the shaped patterns 23, slits Z5 are formed in the vertical direction, and holes H5 are arranged in the vertical direction. At this time, the shape of the hole H5 may be a circle. In addition, as illustrated in FIG. 16D, some of the holes H5 may be formed in a solid pattern B2.

In FIG. 16E, shaped patterns 24 are formed in the foundation layer 21. Herein, in the shaped patterns 24, slits Z6 are formed in the shaped patterns 24. In addition, holes H6 are arranged to surround the slits Z6 and traverse the slits Z6. At this time, the shape of the hole H6 may be a circle. In addition, as illustrated in FIG. 16F, some of the slits Z6 may be formed in a solid pattern B3, and some of the holes H6 may be formed in a solid pattern B4.

In FIG. 16G, shaped patterns 25 are formed in the foundation layer 21. Herein, in the shaped patterns 25, slits Z7 are formed in the horizontal direction, and holes H7 are arranged in the horizontal direction. At this time, the shape of the hole H7 may be an ellipse. In addition, the width of the shaped pattern 25 may be formed to be narrower than that of the shaped pattern 22 of FIG. 16A.

In FIG. 16H, shaped patterns 26 are formed in the foundation layer 21. Herein, in the shaped patterns 26, slits Z8 are formed in the horizontal direction, and holes H8 are arranged in the horizontal direction. At this time, the shape of the hole H8 may be an ellipse. In addition, the width of the shaped pattern 26 may be formed to be thicker than that of the shaped pattern 25 of FIG. 16G.

### Sixth Embodiment

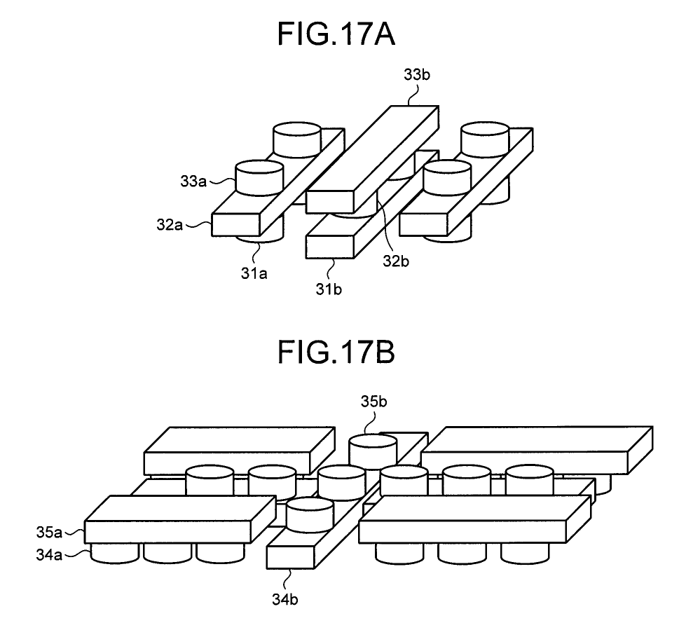

FIG. 17A is a perspective view illustrating an example of stacking holes and slits according to a sixth embodiment.

In FIG. 17A, via patterns 31a are arranged under a line pattern 32a, and via patterns 33a are arranged on the line pattern 32a. In addition, via patterns 32b are arranged on a line pattern 31b, and a line pattern 33b is disposed on the via patterns 32b. Herein, the line patterns 31b, 32a, and 33b are disposed in parallel to each other. In addition, the via pattern 31a and the line pattern 31b are disposed in the same layer. The via pattern 32b and the line pattern 32a are disposed in the same layer. The via pattern 33a and the line pattern 33b are disposed in the same layer.

### Seventh Embodiment

FIG. 17B is a perspective view illustrating an example of stacking holes and slits according to a seventh embodiment.

In FIG. 17B, via patterns 34a are arranged under a line pattern 35a. In addition, via patterns 35b are arranged on a line pattern 34b. Herein, the line patterns 35a and 34b are disposed to be perpendicular to each other. In addition, the via patterns 34a and the line pattern 34b are disposed in the same layer. The via patterns 35b and the line pattern 35a are disposed in the same layer.

### Eighth Embodiment

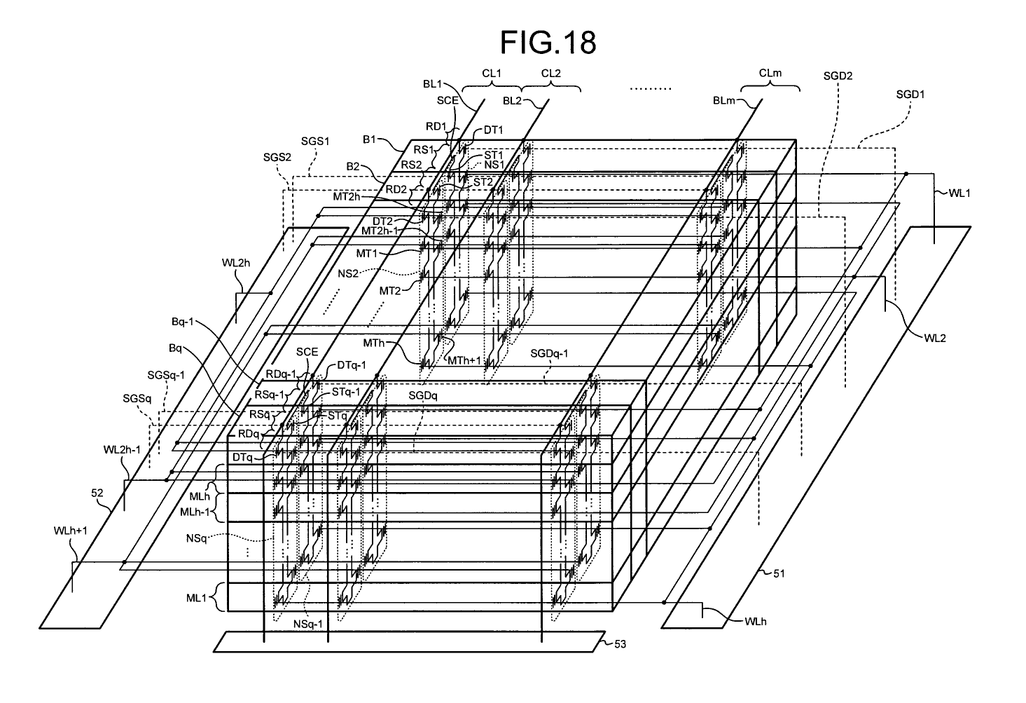

FIG. 18 is a circuit diagram illustrating a schematic configuration of a memory cell array which is applied to a nonvolatile semiconductor storage device according to an eighth embodiment. Further, in the eighth embodiment, a three-dimensional NAND memory will be described in which memory cells are three-dimensionally disposed in a row direction, a column direction, and a height direction. A BiCS (Bit Cost Scalable Memory) will be taken as a specific example of the three-dimensional NAND memory. In addition, in the eighth embodiment, a method is described in which word lines WL1 to WLh and select gate lines SGD1 to SGDq are led out in a direction opposite to the lead direction of word lines WLh+1 to WL2h and select gate lines SGS1 to SGSq.

In FIG. 18, in the memory cell array, q blocks B1 to Bq (where, q is an integer of 2 or more) are disposed in the column direction. Further, the blocks B1 to Bq each include m NAND strings NS1 to NSq which are disposed in the row direction (where, m is a positive integer). Herein, the blocks B1 to Bq each include h cell layers ML1 to MLh (where, h is a positive integer) which are stacked.

The NAND strings NS1 to NSq each are provided with cell transistors MT1 to MT2h, in which the cell transistors MT1 to MT2h are sequentially connected in series. Further, a memory cell in the memory cell array may be configured by one cell transistor. In addition, the cell transistors MT1 to MT2h each may be provided with a charge accumulating area for accumulating charges.

Herein, the cell transistors MT1 to MTh are disposed downwardly in the height direction of the memory cell array, and the disposition turns back in the U shape at the lower end, so that the cell transistors MTh+1 to MT2h are disposed upwardly in the height direction of the memory cell array. In other words, the cell transistors MTh and MTh+1 are disposed in the cell layer ML1, the cell transistors MT2 and MT2h−1 are disposed in the cell layer MLh−1, and the cell transistors MT1 and MT2h are disposed in the cell layer MLh.

In addition, in the memory cell array, m bit lines BL1 to BLm respectively are disposed on columns CL1 to CLm so as to be shared among the q blocks B1 to Bq. Then, a sense amplifier 53 is disposed in the lead direction of the bit lines BL1 to BLm. Further, with the use of the bit lines BL1 to BLm, the NAND strings NS1 to NSq can be selected in the column direction.

In addition, in the memory cell array, the word lines WL1 to WL2h and the select gate lines SGS1 to SGSq and SGD1 to SGDq respectively are disposed on rows RS1 to RSq and RD1 to RDq.

The word lines WL1 to WLh and the select gate lines SGD1 to SGDq are led out in a direction opposite to the lead direction of the word lines WLh+1 to WL2h and the select gate lines SGS1 to SGSq. Then, a row decoder 51 is disposed in the lead direction of the word lines WL1 to WLh and the select gate lines SGD1 to SGDq. A row decoder 52 is disposed in the lead direction of the word lines WLh+1 to WL2h and the select gate lines SGS1 to SGSq.

Herein, the word lines WL1 to WL2h respectively are shared among the cell layers ML1 to MLh through the NAND strings NS1 to NSq which share the same bit line of the bit lines BL1 to BLm and are disposed in rows different from each other. Specifically, in the cell layer ML1, the word lines WLh and WLh+1 are provided in the row direction; in the cell layer MLh−1, the word lines WL2 and WL2h−1 are provided in the row direction; and in the cell layer MLh, the word lines WL1 and WL2h are provided in the row direction. Further, the word lines WL1 to WLh respectively are shared among the q rows RD1 to RDq in the cell layers ML1 to MLh. The word lines WLh+1 to WL2h respectively are shared among the q rows RS1 to RSq in the cell layers ML1 to MLh. In other words, the word line WL1 is shared among the cell transistors MT1 in the q rows RD1 to RDq that are respectively included in the NAND strings NS1 to NSq. The word line WL2 is shared among the cell transistors MT2 in the q rows RD1 to RDq that are respectively included in the NAND strings NS1 to NSq. The word line WLh is shared among the cell transistors MTh in the q rows RD1 to RDq that are respectively included in the NAND strings NS1 to NSq. The word line WLh+1 is shared among the cell transistors MTh+1 in the q rows RS1 to RSq that are respectively included in the NAND strings NS1 to NSq. The word line WL2h−1 is shared among the cell transistors MT2h−1 in the q rows RS1 to RSq that are respectively included in the NAND strings NS1 to NSq. The word line WL2h is shared among the cell transistors MT2h of the q rows RS1 to RSq that are respectively included in the NAND strings NS1 to NSq.

In addition, the NAND strings NS1 to NSq respectively are provided with select transistors DT1 to DTq and ST1 to STq to select the NAND strings in the row direction. Herein, the select transistors DT1 to DTq respectively are provided in the rows RD1 to RDq. In addition, the select transistors ST1 to STq respectively are provided in the rows RS1 to RSq.

In the respective columns CL1 to CLm, the cell transistors MT1 of the NAND strings NS1 to NSq respectively are connected to the bit lines BL1 to BLm through the select transistors DT1 to DTq. Further, in the respective columns CL1 to CLm, the cell transistors MT2h of the NAND strings NS1 to NSq respectively are connected to source lines SCE through the select transistors DT1 to DTq.

In addition, the memory cell array is provided with the select gate lines SGD1 to SGDq and SGS1 to SGSq in the row direction. Herein, the select gate lines SGD1 to SGDq and SGS1 to SGSq respectively are disposed so as to make a pair between the select gate lines SGD1 to SGDq and the select gate lines SGS1 to SGSq in the blocks B1 to Bq. Then, the select gate lines SGD1 to SGDq respectively are connected to the gates of the select transistors DT1 to DTq, and the select gate lines SGS1 to SGSq respectively are connected to the gates of the select transistors ST1 to STq.

Herein, for example, in a case where the NAND string NSs (1≦s≦q) is selected from the q NAND strings NS1 to NSq connected to the bit line BL1, the select transistors DTs and STs of the NAND string NSs are turned on. In addition, in a case where the cell transistor MTr (1≦r≦2h) is selected from the cell transistors MT1 to MT2h of the NAND string NSs, a word line WLr of the cell transistor MTr is activated.

Herein, after the select transistors DT1 to DTq and ST1 to STq respectively are provided on the rows RD1 to RDq and RS1 to RSq, the word lines WL1 to WLh each are shared among the rows RD1 to RDq, and the word lines WLh+1 to WL2h each are shared among the rows RS1 to RSq. Therefore, it is possible to separately select the NAND strings NS1 to NSq, and it is not necessary to lead the word lines WL1 to WL2h to the row decoders 51 and 52 for the rows RD1 to RDq and RS1 to RSq. Accordingly, the number of the lead lines from the word lines WL1 to WL2h can be reduced, so that it is possible to prevent the row decoders 51 and 52 from being massive.

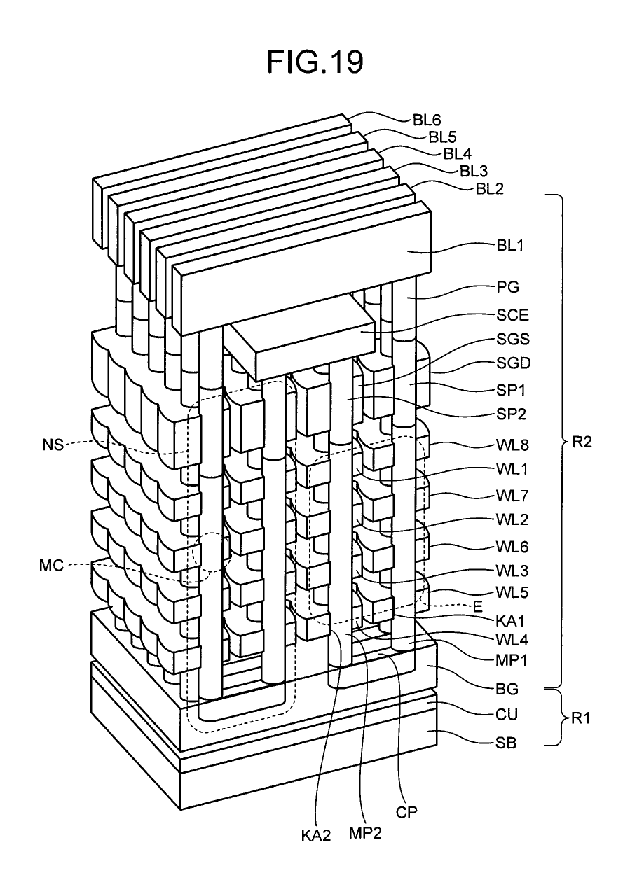

FIG. 19 is a perspective view illustrating a schematic configuration example of the memory cell array of the nonvolatile semiconductor storage device of FIG. 18. Further, the example of FIG. 19 illustrates a method of forming the NAND string NS in which the memory cells MC are formed by stacking only four layers and turning back at the lower end, so that eight memory cells MC are connected in series. In other words, the example of FIG. 19 illustrates the case where m=6, h=4, and q=2 in FIG. 18 are taken as an example.

In FIG. 19, a semiconductor board SB is provided with a circuit region R1, and a memory region R2 is provided on the circuit region R1. Further, the board for the circuit region R1 may be separately provided from the board for the memory region R2.

In the circuit region R1, a circuit layer CU is formed on the semiconductor board SB. A back-gate layer BG is formed on the circuit layer CU, and a connection layer CP is formed in the back-gate layer BG. Cylindrical bodies MP1 and MP2 are disposed on the connection layer CP to be adjacent to each other, and the lower ends of the cylindrical bodies MP1 and MP2 are connected to each other through the connection layer CP. In addition, the word lines WL4 to WL1 corresponding to four layers are sequentially stacked on the connection layer CP, and the word lines WL5 to WL8 corresponding to four layers are sequentially stacked to be adjacent to the word lines WL4 to WL1, respectively. Then, the word lines WL5 to WL8 are passed through by the cylindrical body MP1, and the word lines WL1 to WL4 are passed through by the cylindrical body MP2.

In addition, cylindrical bodies SP1 and SP2 respectively are formed on the cylindrical bodies MP1 and MP2. A select gate electrode SGD which is passed through by the cylindrical body SP1 is formed on the word line WL8 in the uppermost layer, and a select gate electrode SGS which is passed through by the cylindrical body SP2 is formed on the word line WL1 in the uppermost layer.

In addition, the source line SCE which is connected to the cylindrical bodies SP2 is provided on the select gate electrode SGS, and each of the bit lines BL1 to BL6 which are connected to the cylindrical bodies SP1 through plugs PG is formed on the column. Further, the cylindrical bodies MP1 and MP2 may be disposed on the intersection points between the bit lines BL1 to BL6 and the word lines WL1 to WL8.

Herein, the word lines WL1 to WL8 and the select gate electrodes SGD and SGS are periodically changed in width along the row direction. The change periods in width of the word lines WL1 to WL8 and the select gate electrodes SGD and SGS may be set to correspond to the pitch of the cylindrical bodies SP1 in the row direction.

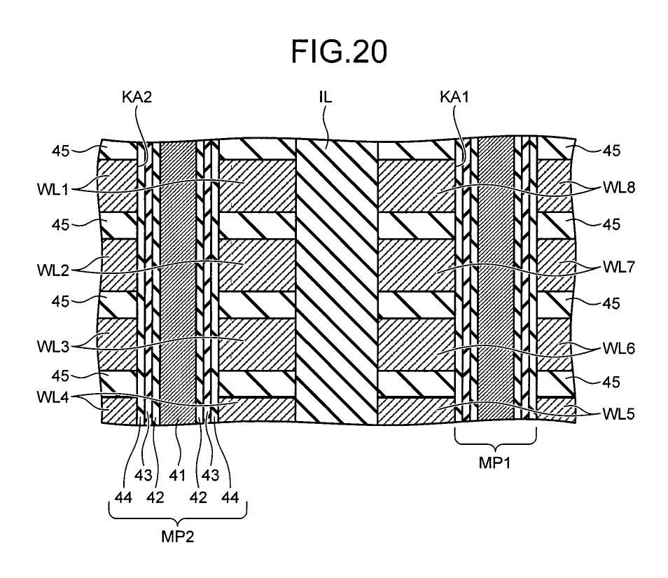

FIG. 20 is a cross-sectional view illustrating a portion E of FIG. 19 in an enlarged manner.

In FIG. 20, an insulating body IL is filled between the word lines WL1 to WL4 and the word lines WL5 to WL8. Interlayer insulating films 45 are formed every between the word lines WL1 to WL4 and every between the word lines WL5 to WL8.

In addition, a hole KA2 is formed to pass through the word lines WL1 to WL4 and the interlayer insulating film 45 in a stacking direction, and a hole KA1 is formed to pass through the word lines WL5 to WL8 and the interlayer insulating film 45 in the stacking direction. The cylindrical body MP1 is formed in the hole KA1, and the cylindrical body MP2 is formed in the hole KA2.

Cylindrical semiconductors 41 are formed in the centers of the cylindrical bodies MP1 and MP2. Further, the cylindrical semiconductor 41 can be formed with channel regions and source/drain layers of the cell transistors MT1 to MT2h of FIG. 18. Tunnel insulating films 42 are formed between the inner surfaces of the holes KA1 and KA2 and the cylindrical semiconductors 41, charge trap layers 43 are formed between the inner surfaces of the holes KA1 and KA2 and the tunnel insulating films 42, and block insulating films 44 are formed between the inner surfaces of the holes KA1 and KA2 and the charge trap layers 43. The cylindrical semiconductor 41, for example, may employ a semiconductor such as Si. The tunnel insulating film 42 and the block insulating film 44, for example, may employ a silicon dioxide film. The charge trap layer 43, for example, may employ a silicon nitride film or an ONO film (three-layer structure of the silicon dioxide film/the silicon nitride film/the silicon dioxide film).

### Ninth Embodiment

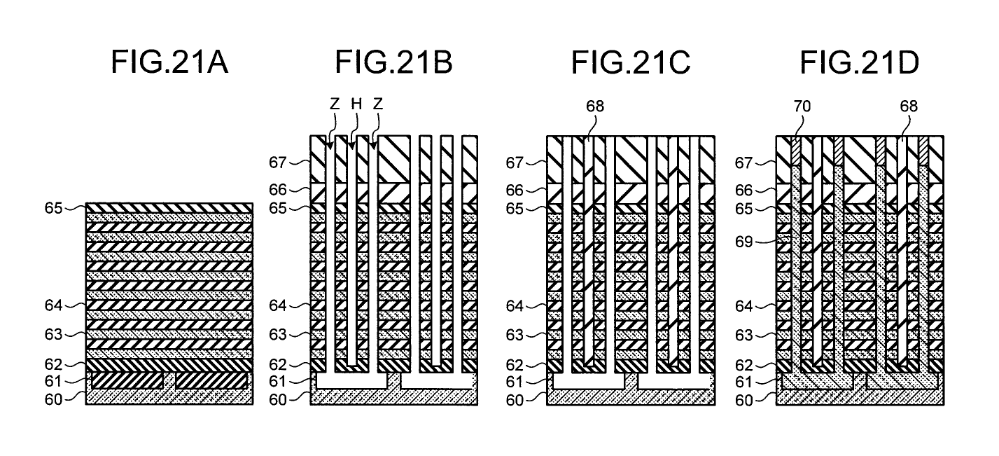

FIGS. 21A to 21D are cross-sectional views illustrating a method of manufacturing a memory cell array which is applied to a nonvolatile semiconductor storage device according to a ninth embodiment. Further, in the ninth embodiment, the case where the memory cells MC of FIG. 19 are formed by stacking only eight layers will be taken as an example.

In FIG. 21A, a foundation layer 60 is provided with connection portions 61. After the connection portions 61 are filled with a sacrificial film, an interlayer insulating film 62 is formed on the foundation layer 60. Further, the foundation layer 60, for example, may employ a semiconductor board. A material of the interlayer insulating film 62, for example, may employ the silicon dioxide film. The sacrificial film filling the connection portions 61 may employ a material having a selectivity lower than that of the interlayer insulating film 62.

Then, impurity-added silicon layers 63 and insulating layers 64 are alternatively stacked using a method such as the CVD. Further, the insulating layer 64, for example, may be the BSG film, or may be the silicon dioxide film. It is preferable to select a material of the insulating layer 64 having an etching rate as similar to that of the impurity-added silicon layer 63 as possible. In addition, B, P, As, or the like may be employed as impurities of the impurity-added silicon layer 63.

Further, an interlayer insulating film 65 is formed on the impurity-added silicon layer 63 of the uppermost layer using a method such as the CVD. Further, a material of the interlayer insulating film 65, for example, may employ the silicon dioxide film.

Next, as illustrated in FIG. 21B, an impurity-added silicon layer 66 is formed on the interlayer insulating film 65 using a method such as the CVD. Further, an interlayer insulating film 67 is formed on the impurity-added silicon layer 66 using a method such as the CVD.

Similarly to the processes illustrated in FIGS. 1A to 1C, FIGS. 2A to 2C, FIGS. 3A to 3C, and FIGS. 4A to 4C, the mask patterns 3a of FIGS. 4A to 4C are formed on the interlayer insulating film 67.

Then, the interlayer insulating films 67, 65, and 62, the impurity-added silicon layers 66 and 63, the interlayer insulating film 65, and the insulating layer 64 are etched through the mask patterns 3a. Accordingly, the slits Z and the holes H are collectively formed in the interlayer insulating films 67, 65, and 62, the impurity-added silicon layers 66 and 63, the interlayer insulating film 65, and the insulating layer 64. At this time, the processing target film 2 of FIGS. 1A to 1C may be provided to correspond to the stacking structure of the interlayer insulating films 67, 65, and 62, the impurity-added silicon layers 66 and 63, the interlayer insulating film 65, and the insulating layer 64.

Next, the sacrificial film of the connection portions 61 is etched through the holes H, so that the sacrificial film of the connection portions 61 is removed.

Next, the slits Z are filled with an insulating body 68 using a method such as the CVD as illustrated in FIG. 21C. Further, a material of the insulating body 68, for example, may employ the silicon dioxide film.

Next, a cylindrical body 69 is filled in the holes H and the connection portions 61 using a method such as the CVD as illustrated in FIG. 21D. Further, a part of the cylindrical body 69 filled in the interlayer insulating film 67 is removed, and the removed portion is filled with the plug 70. Further, the same configuration as that of the cylindrical body MP2 of FIG. 21 may be employed as the cylindrical body 69.

As a method of forming the cylindrical body MP2, the block insulating films 44 are formed on the inner surfaces of the holes H using a method such as the CVD. Next, the charge trap layers 43 are formed on the surfaces of the block insulating films 44 in the holes H using a method such as the CVD. Next, the tunnel insulating films 42 are formed on the surfaces of the charge trap layers 43 in the holes H using a method such as the CVD. Next, the cylindrical semiconductors 41 are filled in the holes H through the tunnel insulating films 42 using a method such as the CVD. Herein, channel layers may be formed in the cylindrical semiconductors 41. Further, instead of filling the cylindrical semiconductors 41 in the holes H, cylindrical insulating bodies may be filled in the holes H after forming semiconductor layers on the surfaces of the tunnel insulating films 42.

Accordingly, without repeating the manufacturing of the holes H, the slits Z, the block insulating films 44, the charge trap layers 43, the tunnel insulating films 42, and the channel layers for every layer, it is possible to stack the memory cells MC. Further, while suppressing the increase in number of the processes, the NAND flash memory can be highly integrated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first shaped pattern in which a plurality of first holes are arranged and of which a width is periodically changed along an arrangement direction of the first holes;
a second shaped pattern in which a plurality of second holes are arranged and of which a width is periodically changed along an arrangement direction of the second holes; and
a slit which is formed along the arrangement direction of the first holes and separates the first shaped pattern and the second shaped pattern.

2. The semiconductor device according to claim 1,
wherein change periods in widths of the first shaped pattern and the second shaped pattern are equal to each other.

3. The semiconductor device according to claim 2,
wherein width of the slit is periodically changed according to the change period in widths of the first shaped pattern and the second shaped pattern.

4. The semiconductor device according to claim 3,
wherein an arrangement pitch of the first holes and an arrangement pitch of the second holes are equal to each other, and
a diameter of the first hole and a diameter of the second hole are equal to each other.

5. The semiconductor device according to claim 4, further comprising:
a first buried material which is filled in the first holes and the second holes; and
a second buried material which is filled in the slit.

6. A semiconductor device comprising:
a first stacked body which is formed by alternatively stacking an impurity-added silicon layer and an interlayer insulating film and of which a width is periodically changed along a row direction;
a second stacked body which is formed by alternatively stacking an impurity-added silicon layer and an interlayer insulating film and of which a width is periodically changed along the row direction;
first holes which are formed along a stacking direction of the first stacked body and are arranged in the first stacked body in the row direction;
second holes which are formed along a stacking direction of the second stacked body and are arranged in the second stacked body in the row direction;
slits which separate the first stacked body and the second stacked body in each of rows;
a first channel layer which is formed in the first hole along the stacking direction of the first stacked body;
a first tunnel insulating film which is formed between an inner surface of the first hole and the first channel layer;
a first charge trap layer which is formed between the inner surface of the first hole and the first tunnel insulating film;
a first block insulating film which is formed between the inner surface of the first hole and the first charge trap layer;
a second channel layer which is formed in the second hole along the stacking direction of the second stacked body;
a second tunnel insulating film which is formed between an inner surface of the second hole and the second channel layer;
a second charge trap layer which is formed between the inner surface of the second hole and the second tunnel insulating film; and
a second block insulating film which is formed between the inner surface of the second hole and the second charge trap layer.

7. The semiconductor device according to claim 6,
wherein change periods in widths of the first stacked body and the second stacked body are equal to each other.

8. The semiconductor device according to claim 7,
wherein widths of the slits are periodically changed according to the change periods in widths of the first stacked body and the second stacked body.

9. The semiconductor device according to claim 8,
wherein widths of the slits are periodically changed according to the change period in widths of the first shaped pattern and the second shaped pattern.

10. The semiconductor device according to claim 9,
wherein a first memory cell includes the first channel layer formed in the first hole, the first tunnel insulating film, the first charge trap layer, the first block insulating film, and the impurity-added silicon layer in a surrounding area of the first block insulating film, and
a second memory cell includes the second channel layer formed in the second hole, the second tunnel insulating film, the second charge trap layer, the second block insulating film, and the impurity-added silicon layer in a surrounding area of the second block insulating film.

11. The semiconductor device according to claim 10,
wherein a memory cell array is configured by three-dimensionally disposing the first memory cell and the second memory cell.

12. The semiconductor device according to claim 11,
wherein a NAND string is configured by connecting cell transistors included in the first memory cell in series in a height direction and connecting cell transistors included in the second memory cell in series in the height direction,
a block is configured by the plurality of NAND strings which are arranged in a row direction, and
the memory cell array is configured by the plurality of blocks which are arranged in a column direction.

13. The semiconductor device according to claim 12, further comprising:
a bit line which selects the NAND strings in the column direction;
a word line which is shared among cell layers through the NAND strings which share the same bit line and are disposed in rows different from each other; and
a select transistor which is provided in each of the NAND strings and selects the NAND strings in the row direction.

14. A method of manufacturing a semiconductor device, comprising:
forming a plurality of core material patterns on a processing target film, the core material patterns being arranged such that a pitch in a second direction is narrower than that in a first direction;
forming a side wall pattern along an outer periphery of the core material pattern, the side wall pattern being formed successively in the second direction and separately in the first direction;
removing the core material pattern after the side wall pattern is formed; and
processing the processing target film such that the side wall pattern is transferred thereon.

15. the method of manufacturing the semiconductor device according to claim 14, further comprising
forming a stopper pattern on the processing target film before the core material pattern is formed.

16. The method of manufacturing the semiconductor device according to claim 14,
wherein diameters of the core material patterns are equal to each other, and
an arrangement pitch of the core material patterns in the first direction is larger than that in the second direction.

17. The method of manufacturing the semiconductor device according to claim 16,
wherein holes are formed inside the side wall pattern, and
slits are formed between the side wall patterns in the second direction.

18. A method of manufacturing a semiconductor device, comprising:
forming a stacked body in which an impurity-added silicon layer and an interlayer insulating film are alternatively stacked;
forming a plurality of core material patterns on the stacked body, the core material patterns being arranged such that a pitch in a column direction is narrower than that in a row direction;
forming a side wall pattern along an outer periphery of the core material pattern, the side wall pattern being formed successively in the column direction and separately in the row direction;
removing the core material pattern after the side wall pattern is formed;
processing the stacked body such that the side wall pattern is transferred thereon, and thus forming first holes which are arranged in the column direction through the stacked body and forming slits which separate the stacked body in the row direction;
forming a block insulating film on an inner surface of the first hole;
forming a charge trap layer on a surface of the block insulating film in the first hole;
forming a tunnel insulating film on a surface of the charge trap layer in the first hole; and
forming a channel layer on a surface of the tunnel insulating film in the first hole.

19. The method of manufacturing the semiconductor device according to claim 18,
wherein diameters of the core material patterns are equal to each other, and
an arrangement pitch of the core material patterns in the row direction is larger than that in the column direction.

20. The method of manufacturing the semiconductor device according to claim 19,
wherein second holes are formed inside the side wall pattern, and
slits are formed between the side wall patterns in the column direction.
